(19) United States
(12) Patent Application Publication
(10) Pub. No.: US 2015/0001520 A1
(43) Pub. Date: Jan. 1, 2015

(54) TRANSPARENT SUPPORTED ELECTRODE FOR AN OLED

(71) Applicant: SAINT-GOBAIN GLASS FRANCE, Courbevoie (FR)

(72) Inventors: Vincent Sauvinet, Grenoble (FR); Fabien Lienhart, San Diego, CA (US); Guillaume Lecamp, Paris (FR)

(73) Assignee: SAINT-GOBAIN GLASS FRANCE, Courbevoie (FR)

(21) Appl. No.: 14/377,657

(22) PCT Filed: Feb. 7, 2013
(86) PCT No.: PCT/FR13/50255

§ 371 Date: Aug. 8, 2014

(30) Foreign Application Priority Data
Feb. 10, 2012 (FR) 1251258

(51) Int. Cl. H01L 51/52

(52) U.S. Cl. CPC H01L 51/5215
USPC 257/40

(57) ABSTRACT

An OLED electrode includes a transparent or translucent non-conductive substrate, with a refractive index between 1.3 and 1.6. A continuous network of lines of a metal or alloy with electrical conductivity at least 5·10⁶ S·m⁻¹ is on a substrate surface. The metal lines have an average width between 0.05 and 3 μm. These metal lines delimit non-metalized fields of average equivalent diameter between 0.1 and 7.0 μm. At least 20% of the metal lines' surface has a tangent forming an angle between 15 and 75° relative to a substrate-electrode plane. A transparent or translucent layer completely covers the metal lines and non-metalized fields. The layer has refractive index between 1.6 and 2.4 and resistivity greater than that of the metal lines and less than 10⁴ Ω·cm. The metal lines and the transparent or translucent layer form a composite layer called an electrode layer.

The present invention relates to a supported electrode intended to be used, preferably as anode, in an organic light-emitting diode.

An organic light-emitting diode (OLED) is an opto-electronic device comprising two electrodes, at least one of which is transparent to visible light, and a stack of thin layers comprising at least one light-emitting layer (layer EL). This light-emitting layer is sandwiched at least between, on the one hand, an electron injection or transport layer (EIL or ETL) situated between the layer EL and the cathode and, on the other hand, a hole injection or transport layer (HIL or HTL) situated between the layer EL and the anode.

The OLEDs that include a transparent electrode support and a transparent electrode in contact therewith are conventionally called OLEDs emitting through the substrate or bottom-emitting OLEDs. The transparent electrode is in this case typically the anode.

Similarly, the OLEDs that include an opaque electrode support are called top-emitting OLEDs, the emission then being done through the transparent electrode which is not in contact with the support, generally the cathode.

Beyond a given potential threshold, the light power of an OLED directly depends on the potential difference between the anode and the cathode. To fabricate OLEDs of large size exhibiting a uniform light power over their entire surface, it is necessary to limit as far as possible the ohmic drop between the current inputs, generally situated at the edge of the OLEDs, and the centre of the OLED. One known way of limiting this ohmic drop is to reduce the resistance per square (R□ or Rₛ, from the term sheet resistance) of the electrodes, typically by increasing their thickness.

Such an increase in the thickness of the electrodes does, however, pose significant problems when it comes to transparent electrodes. In practice, the materials used for these electrodes, for example ITO (Indium Tin Oxide), exhibit an insufficient light transmission and are prohibitively expensive, which make thicknesses greater than 500 nm very uninteresting. In practice, the layers of ITO do not exceed approximately 150 nm.

It has been proposed, for example in the applications US 2004/0150326, WO 2005/008800 and WO2009/07182, to remedy this problem by doubling the transparent electrode or by incorporating therein a network of metal wires or strands that are sufficiently thin to be invisible to the naked eye. These wires make it possible to improve the equivalent square resistance of the whole (TCO+grid) and thus bring the current more effectively to the centre of the OLED module by limiting the ohmic losses and by therefore improving the light efficiency pro rata. On the other hand, the intrinsic losses of light trapped in the OLED stack by total reflection are not improved by these grids according to the prior art.

The above prior art documents recommend limiting the total surface area covered by the metal strands to avoid undesirably reducing the light is transmission of the electrode. Thus, WO 2005/008800 teaches that the metal structure preferably does not cover more than 10% of the surface of the substrate. US2004/0150306 explains in paragraph [0040] that the light transmission decreases with the size of the fields not covered by the metal structure, and finally, the application WO2009/07182 recommends a hole size that is big in relation to the width of the metal strands in order to obtain a high light transmission. Hitherto, there has thus been a technical prejudice whereby the person skilled in the art had to find a trade-off between an excessively high open rate (percentage of surface not covered by the metal structure) not allowing the desired resistances per square to be obtained and an excessively low open rate undesirably opacifying the transparent electrode.

The present invention is based on the surprising discovery that reducing the open rate of a transparent electrode did not necessarily result in a reduction in the quantity of light extracted from the layer EL, via the layer HTL or ETL, and the transparent layer of the electrode, to the glass support and, finally, the air.

Complex phenomena linked to the reflection and the refraction of the light produced in the layer EL in fact have just as much influence on the quantity of light reaching, from the layer EL, the air. In fact, the stack of the layers HTL/EL/ETL exhibits a high refractive index, close to 1.8, whereas the refractive index of the transparent support, when it is made of ordinary glass is approximately 1.5 and that of the air equal to 1. The total internal reflection of the light at the different interfaces (stack/transparent electrode, transparent electrode/support and support/air) makes the OLED a waveguide in which a very large part of the light is reflected a great number of times and ends up being absorbed.

It is known practice to reduce the phenomenon of the total internal to reflection of the light at the interfaces of the OLEDs by conventional light-diffusing means such as dulled surfaces or the presence of diffusing elements (microparticles, nanoparticles, micropores or nanopores). These diffusing elements can be incorporated in the substrate or in the electrode or else they can be inserted between the electrode and the substrate in the form of an is additional diffusing layer, as is described for example in the international application WO2009/116531.

The effectiveness of these diffusing elements is, however, limited by the fact that they have an undesirable opacifying effect when they are present in excessive quantities.

The present invention is based on the idea of reducing the phenomenon of total internal reflection of the light at the interface between the transparent electrode (index close to that of the HTL/EL/ETL stack) and the glass support (n=1.5) not by virtue of the presence of diffusing elements, but
by rendering the interface concerned inaccessible to the light rays likely to be reflected thereby, and
by reorienting these light rays so as to reduce their angle of incidence and allow them to pass into the glass support.

In other words, for the rays likely to undergo a total reflection at the interface between the transparent electrode and the glass, the areas of the interface between the transparent electrode and the glass are mostly “in the shadow” of the strands of the grid on which they are reflected by being deflected because of the geometry of the strands.

The Snell-Descartes law (n₁ sin θ₁=n₂ sin θ₂) can be used to calculate the angle of incidence θ₁ beyond which a light ray is totally reflected (θ₂=90°) by an interface between two media of different optical indices. By way of example, it is thus possible to calculate that a light ray originating from the stack of high index layers of an OLED and striking the interface between the transparent electrode (n=1.8) and the support (n=1.5) is totally reflected by this interface when its angle of incidence is greater than approximately 56°. This angle is equal to 52° and 49° for a transparent electrode exhibiting respectively an index equal to 1.9 and 2, on a support made of glass (n=1.5).

In a composite electrode as described in the documents US 2004/0150326, WO 2005/008800 and WO2009/07182, all the rays with excessively high θ₁, hereinafter called “grazing” rays, are thus reflected and do not penetrate into the underlying glass substrate. To prevent these grazing rays from striking the electrode/substrate interface, the Applicant proposes in the present invention to reduce the average size of the non-metalized fields. In practice, for a given height of metal strands, the grazing rays have all the fewer chances of arriving at the electrode/substrate interface when the average size of the fields, or the average distance between strands, is small.

To put it another way, for a given average size of non-metalized fields, the grazing rays have all the fewer chances of arriving at the electrode/substrate interface when the height of the metal strands is high.

Bringing the metal strands closer together in this way has hitherto not been proposed because of the existence of a technical prejudice according to which reducing the percentage of the non-metalized surface, hereinafter called “open rate”, would be reflected in an undesirable reduction in the light fraction transmitted by the composite electrode.

Now, the Applicant has found that, surprisingly, this prejudice was unfounded and that, in certain conditions, reducing the open rate of the composite electrode did not result in a significant reduction in the quantity of light extracted from the OLED. The absence of reduction of the quantity of light transmitted by the composite electrode, despite a reduction in the open rate thereof, is probably due to the fact that the light rays reflected by the metal strands are reoriented and, after having been reflected by the metal back electrode, strike the non-metalized surface of the interface with a smaller angle of incidence, ultimately allowing them to penetrate into the underlying glass substrate.

The subject of the present invention is consequently a transparent composite electrode for OLED comprising, on a transparent substrate, an electrode layer formed by a continuous metal network, of regular or irregular grid type, incorporated in a transparent conductive layer, and in which the average size of the non-metalized meshes is reduced compared to the composite electrodes hitherto known.

More specifically, the subject of the present invention is an electrode for organic light-emitting diode, comprising

(a) a non-conductive substrate, transparent or translucent, with a refractive is index of between 1.3 and 1.6,
(b) a continuous network of metal lines consisting of a metal or metal alloy exhibiting an electrical conductivity at least equal to 5·10⁶ S·m⁻¹, deposited on at least one surface area of the substrate (a), the metal lines having an average width L of between 0.05 and 3 μm, and delimiting a plurality of non-metalized fields having an average equivalent diameter D of between 0.1 and 7.0 μm, the ratio D/L being between 0.8 and 5,
(c) a transparent or translucent layer exhibiting a refractive index of between 1.6 and 2.4, preferably between 1.75 and 2.05, and a resistivity greater than that of the continuous network of metal lines and less than 10⁴ Ω·cm, preferably less than 10³ Ω·cm, said layer completely covering the network of metal lines and the non-metalized fields,
the continuous network of metal lines (b) and the transparent or translucent layer (c) together forming a composite layer called electrode layer.

Another subject of the invention is an OLED containing such an electrode, this electrode preferably being the anode, and the OLED preferably being an OLED emitting through the substrate.

The non-conductive substrate used in the present invention can be any substrate made of mineral or organic glass conventionally used in the field of OLEDs. It can also be a sheet or a flexible film of plastic material.

The expression transparent or translucent substrate should be understood to mean a substrate exhibiting a light transmission (T_{L}) of the light (determined according to standard NF EN 410) at least equal to 85%. It generally concerns planar and flat substrates, possibly polished, having two main surfaces and a wafer. The thickness of the substrate is preferably between 0.05 and 5 mm.

The term refractive index in the present application should be understood to mean the refractive index of the material determined at a wavelength of 550 nm. Some anisotropic materials used as transparent substrates, for example mono- or bi-oriented plastic films, can exhibit more than one refractive index. In this case, at least one of the refractive indices of the anisotropic substrate has a value of between 1.3 and 1.6 at 550 nm. In practice, in as much as the emission of the light from an OLED is produced at different incidences and according to different polarizations, at least one non-zero component of the electromagnetic radiation of the OLED will be emitted along the axis having a refractive index of between 1.3 and 1.6.

The continuous network of metal lines is generally deposited on just one of the main surfaces of the substrate. This main surface is covered, over one or more areas, by the continuous network of metal lines. When it is a single area, the latter can cover the whole of the main surface of the substrate or only a part of this surface. It may in fact be advantageous to leave free, for example, a peripheral area of this surface. It is important to note that the area of the area or areas covered by the continuous network of metal lines will be used in the present application as reference value, for example for the definition and calculation of the open rate or of the substance weight of the metal network.

The metal or metal alloy forming the continuous network of metal lines (b) preferably has an electrical conductivity of between 6·10⁶ S·m⁻¹ and 6.3·10⁷ S·m⁻¹, the latter value corresponding to the electrical conductivity of silver, greater than that of all the other metals. The metal or metal alloy is preferably chosen from the group formed by silver, copper, aluminum, gold, and the alloys based on these metals.

Silver is the metal material preferred out of all, because it exhibits both the best possible electrical conductivity and a reflection coefficient greater than that of all the other metals. It is, however, a metal that is considerably more expensive than aluminum and copper.

In a particularly advantageous embodiment of the electrode of the present invention, the continuous network of metal lines is consequently formed by a network based on silver-plated aluminum and/or copper plated with silver. The silver plating can be done by electrochemical methods that are simple and well known in the art. Such a composite network of silver-plated copper or aluminum exhibits the reflection coefficient of silver and has a cost close to that of the underlying metal (Al or Cu).

In the present application, the geometry of the continuous network of metal lines is of great importance. It is characterized by the following parameters:

The average equivalent diameter (D) of the non-metalized fields: this average equivalent diameter is the average of all the equivalent diameters of the non-metalized fields, also called “openings”, determined by image analysis on an electron microscopy or optical snapshot. The equivalent diameter of a non-metalized field is the diameter of a circle of the same surface area as the non-metalized field.

The open rate (T) is the ratio of the non-metalized surface to the total surface (non-metalized surface+metalized surface) of the area covered by the continuous network of metal lines. This open rate is measured, like the average equivalent diameter, by image analysis.

It is important to distinguish this open rate (T) from what is conventionally called the light transmission (T_{L}) of the electrode layer. The light transmission, measured in accordance with standard NF EN 410, is the ratio of the light flux transmitted by a material to the incident light flux. The light transmission depends, among other things, on the absorption coefficient and on the thickness of the material concerned. In the case of a composite electrode according to the invention, the light transmission (T_{L}) is always significantly lower than the open rate. In practice, to the absorption and the reflection of the light by the continuous network of metal lines (b) are added the absorption and the reflection of the light by the layer (c). By way of example, a composite electrode consisting of a metal network having an open rate of 70%, which is filled and covered by a transparent layer (c) exhibiting (in the absence of the network (b)) a light transmission of 80%, will overall have a T_{L} of approximately 56%.

The average width L of the metal lines is obtained by calculation from the two experimental quantities defined above (D and T), by likening the continuous network to a regular metal grid comprising square openings of side (C) using the formula:

$$L = C \frac{1 - \sqrt{T}}{\sqrt{T}} \qquad ( 1 )$$

where
T is the open rate of the continuous network of metal lines and

$$C = D \frac{\sqrt{π}}{2} ;$$

D being the average equivalent diameter of the continuous network of metal lines.

The average equivalent diameter D of the continuous network of metal lines of the electrode of the present invention is between 0.1 and 7.0 μm, preferably between 0.3 and 4.0 μm, more preferably between 0.4 and 3.0 μm and ideally between 0.5 and 2.0 μm.

The continuous network of metal lines must obviously be such that the distribution of the equivalent diameters of the non-metalized fields are relatively narrow. This is a condition that is essential to a good uniformity of lighting. The electrode is preferably free of non-metalized fields that are visible to the naked eye, because this visibility would be sensed by the viewer as a defect. More particularly, the ambient surface of the non-metalized fields having an equivalent diameter greater than 15 μm preferably does not exceed 5%, in particular does not exceed 2% and ideally does not exceed 1% of the total surface over which the continuous network of metal lines extends.

Although the open rate of the continuous network of metal lines can in principle be contained between relatively wide limits, for example between 20% and 80% of the area covered by said network, the Applicant has observed that it was more advantageous to use open rates of the electrode layer of between 30 and 70%, preferably between 30% and 60%, and even between 35% and less than 50%.

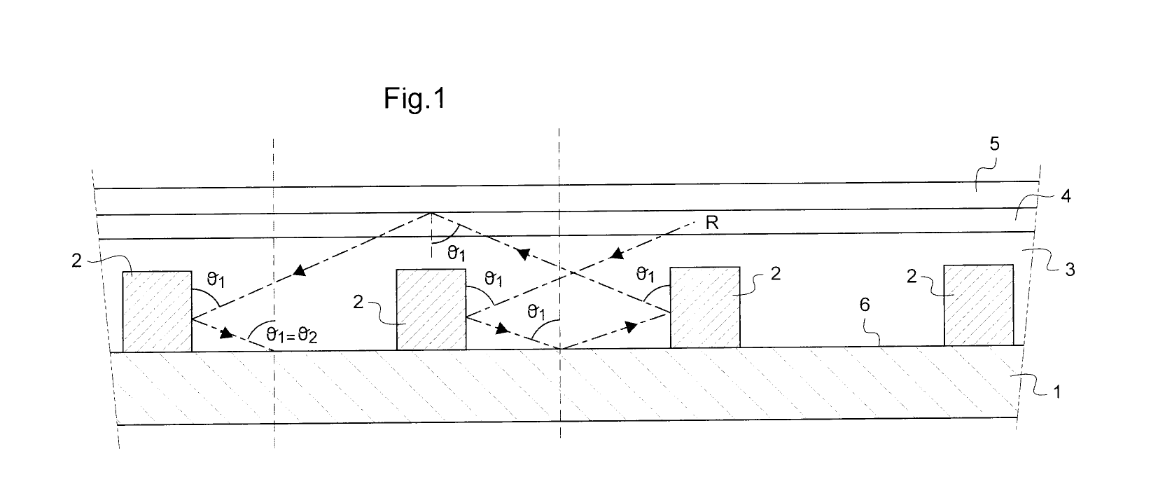

As explained in the introduction, the present invention is based on the principle of the reorientation of the grazing light rays emitted by the layer EL and striking the network of metal lines. For this reorientation to be effective, it has to be reflected by a reduction in the angle of incidence of the light ray when the latter, after having been reflected for example by the back electrode, comes back to once again strike the substrate/electrode layer interface. By considering a geometrical optical model of an OLED according to the invention where the continuous metal network would comprise only parallel surfaces and surfaces at right angles to the substrate/electrode layer interface, such a reorientation would not take place and the light ray would come back with the same angle of incidence on the substrate/layer surface, as has been represented in FIG. 1. For the reorientation to be effective, the surfaces of the continuous metal network should ideally include surfaces forming an angle close to 45° in relation to the plane of the substrate and of the electrodes.

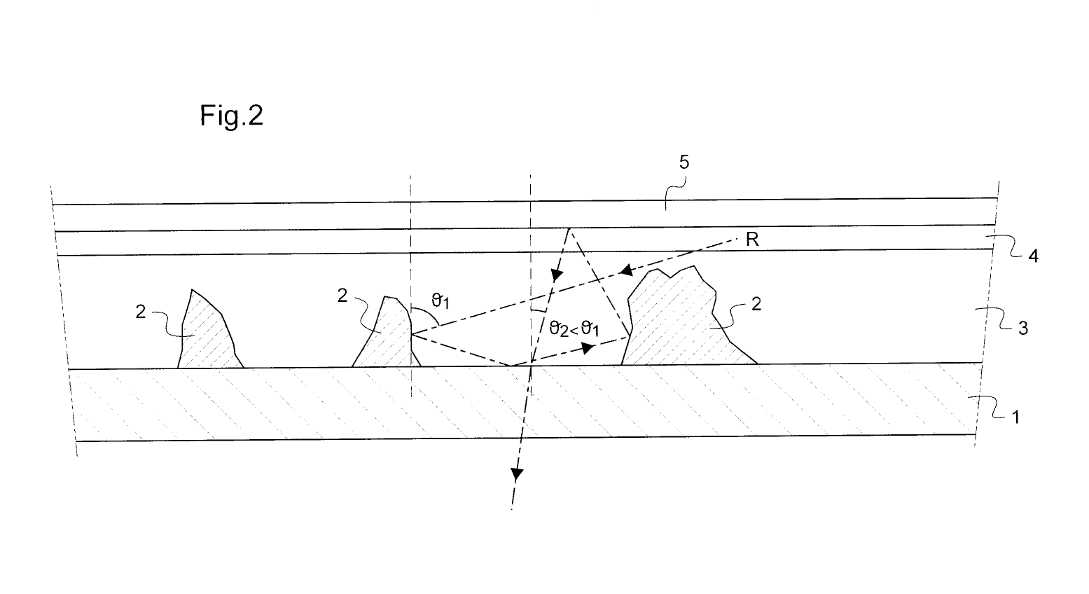

The continuous network of metal lines of the electrode of the present invention is consequently essentially free of surfaces that are parallel or at right angles to the plane of the interface between the electrode layer (c) and the substrate (a). This technical feature obviously does not concern the contact surface between the network and the substrate but only the contact surface between the metal network (b) and the layer (c). A cross section of such an electrode according to the invention is represented in FIG. 2.

The continuous network of metal lines (b) is advantageously free, in a large proportion, that is to say more than 30%, preferably more than 50% and even better more than 80%, of surfaces that are parallel or at right angles to the plane of the interface between the electrode layer and the substrate.

In a particularly advantageous embodiment of the present invention, at least 20%, preferably at least 40%, more preferably at least 60% of the surface of the continuous network of metal lines have an angle of between 15 and 75°, preferably between 25 and 65°, and in particular between 33° and 57° in relation to the plane of the substrate and of the electrode, these percentages and these angles relating to the network (b)/layer (c) interface. These angles can be evaluated as being the slopes of the tangents to the metal network on a transversal profile: they can be determined by scanning electron microscopy (SEM) or by transmission electron microscopy (TEM), followed by an image analysis, of a cross section of the electrode, obtained for example by clean break at low temperature or cutting.

For the continuous metal network to prevent the grazing light rays from striking the non-metalized fields, the metal lines must have a certain height. This height is preferably at least equal to a third of the width L of the metal lines and preferably between L/2 and L/1.5.

The weight per surface area of the continuous network of metal lines (b) is preferably between 4 and 1000 μg/cm² of electrode, in particular between 20 and 600 μg/cm² of electrode, and ideally between 50 and 300 μg/cm² of electrode. Obviously, when the metal network essentially consists of aluminum, possibly covered with silver, these values must be divided by a factor of approximately 4.

The “openings” of the continuous network of metal lines are filled by an electroconductive transparent or translucent material. This material exhibits a refractive index of between 1.70 and 2.40, preferably between 1.75 and 2.05, in particular between 1.80 and 1.98 and a resistivity greater than that of the continuous network of metal lines and less than 10⁴ Ω·cm. This layer not only fills the voids left by the metal network but completely covers the latter. For the fabrication of OLEDs of good quality exhibiting a uniform brightness, it is important for this planarization layer (c) to have as little roughness as possible. In particular, in the case where this layer is a metal oxide, its roughness RMS is preferably less than 5 nm, in particular less than 3 nm.

For this transparent or translucent layer (c), it is in principle possible to use any transparent or translucent conductive material exhibiting a sufficiently high refractive index, close to the average index of the stack HTL/EL/ITL, and an electrical conductivity less than that of the metal network. Examples of such materials that can be cited include the transparent conductive oxides such as aluminum-doped zinc oxide (AZO), indium-doped tin oxide (ITO), tin and zinc oxide (SnZnO) or tin dioxide (SnO₂). These materials advantageously have an absorption coefficient very much lower than that of the organic materials forming the stack HTL/EL/ITL, preferably an absorption coefficient less than 0.005, and in particular less than 0.0005.

When the transparent conductive oxide is not ITO, it may be necessary to cover the layer (c) with a thin additional layer exhibiting an output work function greater than that of the layer (c), for example a layer of ITO, of MoO₃, WO₃ or V₂O₅.

The techniques for deposition of these oxides such as cathode sputtering, magnetron vacuum deposition, sol-gel or pyrolysis methods, do not generally result in layers that are smooth enough for an application as OLED electrode. It will consequently usually be necessary to proceed, after deposition, with a polishing step.

PEDOT (poly(3,4-ethylenedioxythiophene)) is a known electrically conductive organic polymer which could form an interesting alternative to the conductive oxides mentioned above, provided that its refractive index is adjusted, for example, by incorporating nanoparticles of a high index oxide, such as titanium oxide. The possibility of depositing this polymer in liquid form makes it possible in fact to achieve layers (c) with sufficient surface smoothness, which could render the polishing step superfluous.

The present invention also encompasses embodiments where the layer (c) acts not only as anode, but also as hole transport layer (HTL), in other words the embodiments where the electrode does not include an electron layer and an HTL layer that are separate. The HTL deposited in the production of an OLED stack is in fact a material that can perfectly well be used both as HTL and as anode because a low conductivity is sufficient because of the proximity of the metal grid on which it is deposited. In this case, it may be necessary to position under the layer (c) a thin additional layer exhibiting a suitable output work function, for example a layer of ITO, of MoO₃, WO₃ or V₂O₅.

It is known practice to incorporate, in certain transparent OLED layers, particles or pores, intended to favor the extraction of the light by diffusion thereof. The layer (c) of the electrode of the present invention can thus contain a certain fraction of particles or of pores having an average equivalent diameter of between 0.05 and 2 μm, preferably between 0.1 and to 0.5 μm. The presence of such particles, while it does effectively assist in the extraction of the light, is, however, reflected, with excessively high concentrations, in a certain opacification of the layer. By virtue of the particular geometry of the composite electrode layer of the present invention, the problems of extraction of the light are largely resolved and the presence of diffusing particles or pores becomes less important or even superfluous. The layer (c) of the composite electrode layer can consequently contain less than 1% by volume, preferably less than 0.8% by volume of pores or of particles having an average equivalent diameter of between 0.05 and 2 μm. It is preferably a transparent layer essentially free of such diffusing pores and particles having an average equivalent diameter of between 0.05 and 2 μm.

The composite electrode layer of the present invention formed by the continuous network of metal lines (b) and by the transparent or translucent layer (c) preferably has a total thickness of between 0.1 and 3 μm, in particular between 0.2 and 1.0 μm, and more preferentially between 0.3 and 0.6 μm.

Its resistance per square (R□) is preferably as low as possible and in particular less than 5ω/□, preferably between 0.05 and 2.0ω/□, in particular between 0.1 and 1ω/□.

The electrode of the present invention can be used for the fabrication of OLEDs according to methods that are familiar to the person skilled in the art using known steps and materials.

This fabrication does not present any particular difficulty associated with the technical features of the electrode. The person skilled in the art will obviously be careful not to compromise the integrity of the electrode so as not to degrade the intrinsic qualities thereof.

The layers of the stack HTL/EL/ITL of the OLED of the present invention preferably have an average refractive index of between 1.7 and 2.1, that is to say an index close to that of the translucent or transparent layer (c) directly in contact with the stack.

The supported electrode of the present invention can be fabricated for example as follows:

A continuous metal layer made of aluminum or silver is deposited by magnetron cathode sputtering on a sheet of mineral glass in a thickness of approximately 300 nm. The substrate bearing the metal layer is then subjected to a photolithoetching operation so as to obtain a regular metal grid with openings (non-metalized fields) having a surface of approximately 3 μm² (=equivalent diameter of 1.95 μm). The open rate T, measured by image analysis, is 48%.

From the parameters D and T, the formula (1) above is used to calculate the width L of the metal lines of the grid: 0.76 μm.

The layer which is thus “open work” is then subjected to a limited chemical attack, the aim of which is to texture the metal surface of the grid so as increase the proportion of surfaces have an angle close to 45° in relation to the plane of the electrode.

A layer of AZO is then deposited on all of the textured metal network by cathode sputtering in a thickness of the order of 500 nm. This layer is then subjected to a polishing so as to obtain a surface roughness less than 2 nm.

The idea underlying the present invention is illustrated in the appended figures in which:

FIG. 1 represents a cross-sectional view of an OLED containing a comparative electrode,

FIG. 2 represents a cross-sectional view of an OLED containing an electrode according to the invention.

More particularly, FIG. 1 shows an OLED with a non-conductive support or substrate (1) bearing a composite anode consisting of a continuous network of metal lines (2), the voids of which are filled by a transparent conductive oxide (3). The composite anode is topped by a stack of layers HTL/EL/ETL (4) in contact with the cathode (5). All of the surfaces of the continuous network of metal lines (2) are either parallel or at right angles to the anode/support interface (6). A ray R having a high angle of incidence θ₁ (greater than 57°) is reflected by the interface (6), the surface of the continuous metal network (2), the cathode (5) then once again strikes the interface (6) with an angle θ₂ greater than θ₁.

The components of the electrode according to the invention represented in FIG. 2 are the same as those of FIG. 1. The only difference lies in the fact that the surfaces of the metal network (2) are neither at right angles nor parallel to the interface (6) between the electrode (3) and the support (1). The phenomenon of trapping of the light ray is thus impossible. A ray R having a high angle of incidence θ₁ is reflected by the interface (6), the surface of the continuous metal network (2), the back electrode (cathode) (5) then once again strikes the interface (6) with an angle θ₂ less than θ₁ and sufficiently small to be refracted by the interface (6).

1. An electrode, comprising
a transparent or translucent non-conductive substrate with a refractive index of between 1.3 and 1.6,
a continuous network of metal lines consisting of a metal or metal alloy having an electrical conductivity at least equal to 5·10⁶ S·m⁻¹, deposited on at least one surface area of the substrate, the metal lines having an average width L of between 0.05 and 3 μm and delimiting a plurality of non-metalized fields having an average equivalent diameter D of between 0.1 and 7.0 μm, and
a transparent or translucent layer having a refractive index of between 1.6 and 2.4 and a resistivity greater than that of the continuous network of metal lines and less than 10⁴ Ω·cm,
wherein the transparent or translucent layer completely covers the network of metal lines and the non-metalized fields,
the continuous network of metal lines and the transparent or translucent layer together form a composite electrode layer,
a ratio D/L is between 0.8 and 5,
at least 20% of a surface of the continuous network of metal lines has a tangent forming an angle of between 15 and 75° relative to a plane of the substrate and of the electrode, and
wherein the electrode is adapted for an organic LED.

2. The electrode as claimed in claim 1, wherein the average equivalent diameter D is between 0.3 and 4.0 μm.

3. The electrode of claim 1, wherein the metal lines have a height at least equal to L/3.

4. The electrode of claim 1, wherein an open rate of the electrode layer is between 20 and 80%.

5. The electrode of claim 1, wherein the metal or metal alloy forming the continuous network of metal lines has an electrical conductivity of between 6·10⁶ S·m⁻¹ and 6.3·10⁷ S·m⁻¹.

6. The electrode as claimed in claim 5, wherein the metal or metal alloy is selected from the group consisting of silver, copper, aluminum, gold, and any alloy based on any of these metals.

7. The electrode of claim 1, wherein the continuous network of metal lines is a network based on silver-plated aluminum and/or copper.

8. The electrode of claim 1, wherein the continuous network of metal lines is essentially free of surfaces parallel or perpendicular to a plane of an interface between the transparent or translucent layer and the substrate.

9. The electrode of claim 1, wherein a weight per surface area of the continuous network of metal lines is between 4 and 1000 μg/cm² of electrode.

10. The electrode of claim 1, wherein the transparent or translucent layer (c) has a surface roughness RMS less than 5 nm.

11. The electrode of claim 1, wherein the transparent or translucent layer (c) is a transparent layer which is essentially free of pores and of diffusing particles having an average equivalent diameter of between 0.05 and 2 μm.

12. The electrode of claim 1, wherein a resistance per square (R□) of the electrode layer is less than 5Ω/□.

13. The electrode of claim 1, wherein the electrode layer has a thickness of between 0.1 and 3 μm.

14. The electrode of claim 1, further comprising a layer covering the transparent or translucent layer and having an output work function greater than the transparent or translucent layer.

15. An organic light-emitting diode comprising the electrode of claim 1.
